(19) United States
(12) Patent Application Publication
(10) Pub. No.: US 2004/0224473 A1
(43) Pub. Date: Nov. 11, 2004

(54) Using metal peatures to align etches of compound semiconductors

(75) Inventors: Lay-Lay Chua, Cambridge (GB); Yang Yang, Gillette, NJ (US); Chun-Ting Liu, Hsin-chu City (TW)

Correspondence Address: HITT GAINES P.C., P.O. BOX 832570, RICHARDSON, TX, 75083, US

(73) Assignee: Lucent Technologies Inc., Murray Hill, NJ

(21) Appl. No.: 10/430,499

(22) Filed: May 6, 2003

(51) Int. Cl. H01L 21/331

(52) U.S. Cl. 438/313

(57) ABSTRACT

The present invention provides a method for manufacturing bipolar transistors having reduced parasitic resistance and therefore improved performance compared to conventionally made bipolar transistors. Dry etching of a compound semiconductor in the transistor allows a perimeter of the compound semiconductor layer to be substantially coextensive with a perimeter of an overlying metal layer. This, in turn, reduces the gap between the compound semiconductor and subsequently deposited metal layer to be minimized, thereby reducing the parasitic resistance of the bipolar transistor.

### TECHNICAL FIELD OF THE INVENTION

The present invention is directed, in general, to novel bipolar transistors and methods for manufacturing bipolar transistors containing compound semiconductors, and more specifically, methods to align vertical etches in compound semiconductors.

### BACKGROUND OF THE INVENTION

In high speed device applications of the microelectronic and telecommunication industries, II-VI and III-V compound semiconductor materials offer a number of advantages over devices based on silicon semiconductors. For instance, the high electron mobility of III-V substrates, such as Indium Phosphide (InP) or Indium Gallium Arsenide (InGaAs) are advantageous in the high speed active device structures used in optical fiber communication applications that include bipolar transistors. Also, the wide band gap properties of compound semiconductor materials make them useful in modulator driver applications in optoelectronic devices. There is currently great interest in scaling active devices containing compound semiconductors to smaller sizes to improve device performance and enhance integration level.

The scaling of transistors containing II-VI and III-V compound semiconductors to smaller sizes has been problematic, however. One of the problems encountered, for example, is the phenomenon of asymmetric etch rates for compound semiconductors. That is, the rate at which compound semiconductors can be etched depends upon the orientation of the semiconductor crystal. For example, in the presence of conventional wet etchants, such as aqueous mixtures of HCl and H₃PO₄, an emitter comprising a III-V compound semiconductor, such as Indium Phosphide (InP) has an etch rate that is higher in the [001] or [010] direction than in the [011] or [011] direction. Ratios of etch rates along the [001] versus [011] direction can range from about 5:1 to 10:1, for example. Anisotropic etches rates make it difficult to control the lateral feature sizes of compound semiconductors when preparing self-aligned structures.

An undesirable consequence of conventional methods of etching compound semiconductors is that etching causes undercutting of mask features more in one lateral dimension of the semiconductor crystal than in another direction. For instance, to insure that the compound semiconductor does not extend outside of the boundary defined by the metal mask along a slow-etching crystal direction, longer etching times are used. But the longer etching time causes a larger undercut in the fast-etching direction than in the slow-etching direction. The presence of the undercut, in turn, results in mechanical instability and in extreme instances mechanical failure of the device structure. Undercut also undesirably increases parasitic resistance in the active device. For example, the presence of undercut contributes to the minimum allowable distance between an emitter and a metal base formed on the base semiconductor of a bipolar transistor for a given performance specification. This distance contributes increased parasitic resistance in the bipolar transistor because current has to travel farther between the base electrode and the emitter semiconductor. The parasitic resistance, in turn, contributes to decreasing the device performance, as measured by the maximum oscillation frequency, for example. Undercutting caused by anisotropic etches rates therefore presents a fundamental problem in improving compound semiconductor device performance and yield.

Accordingly, an objective of the invention is a method of etching II-VI and III-V compound semiconductors so as to avoid excessive undercutting and therefore produce devices that do not encounter the above-mentioned difficulties.

### SUMMARY OF THE INVENTION

To address the above-discussed deficiencies, one embodiment of the present invention provides a method of manufacturing a bipolar transistor. The method includes depositing a compound semiconductor layer over a semiconductor substrate and forming a patterned metal layer on the compound semiconductor layer. The method further includes performing a dry etch of the compound semiconductor layer in a manner that uses the metal layer to align the dry etch.

Another embodiment of the invention is a bipolar transistor. The bipolar transistor includes a semiconductor substrate, one of an emitter or collector comprising a compound semiconductor and contacting a base, and a metal layer over the emitter. A perimeter of the emitter or collector is substantially coextensive with a perimeter of the metal layer.

Yet another embodiment of the present invention is an integrated circuit, comprising the above described bipolar transistor and a metal base on the base. The metal base has a gap between the perimeter of the emitter and the metal base.

### BRIEF DESCRIPTION OF THE DRAWINGS

The invention is best understood from the following detailed description, when read with the accompanying FIGUREs. Various features may not be drawn to scale and may be arbitrarily increased or reduced for clarity of discussion. Reference is now made to the following descriptions taken in conjunction with the accompanying drawings, in which:

FIGS. 1A-1E illustrate sectional views of a bipolar transistor at various stages of manufacture;

FIG. 2 schematically illustrates a sectional view of a portion of a bipolar transistor; and

FIG. 3 schematically illustrates a sectional view of a portion of an integrated circuit incorporating a bipolar transistor.

### DETAILED DESCRIPTION

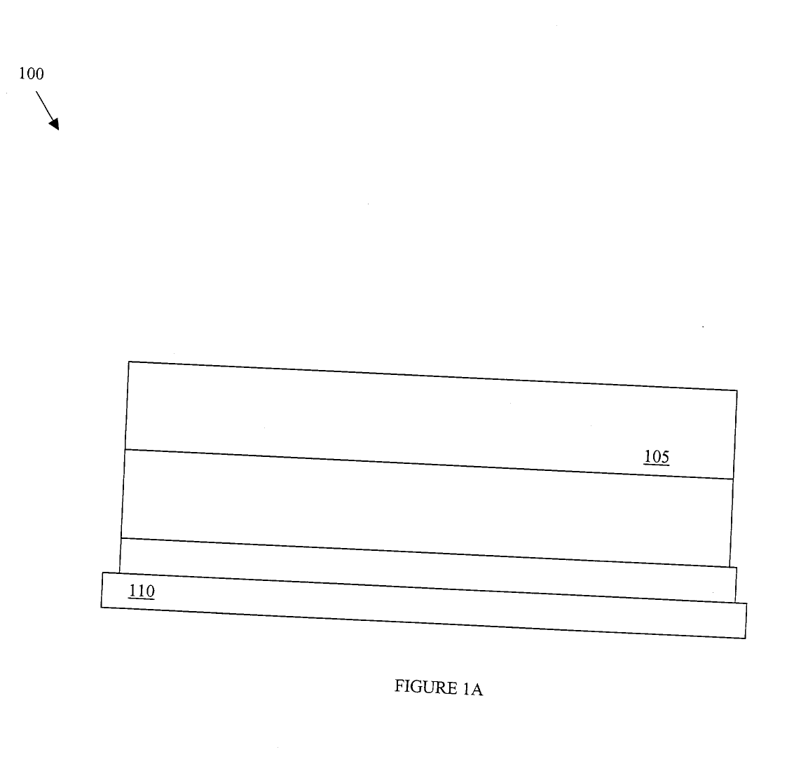

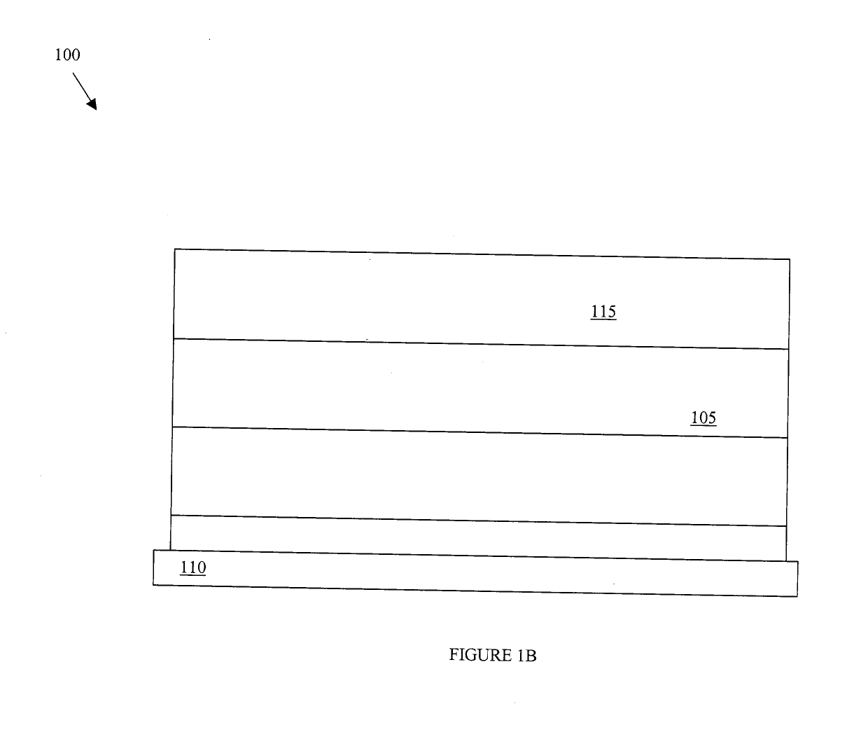

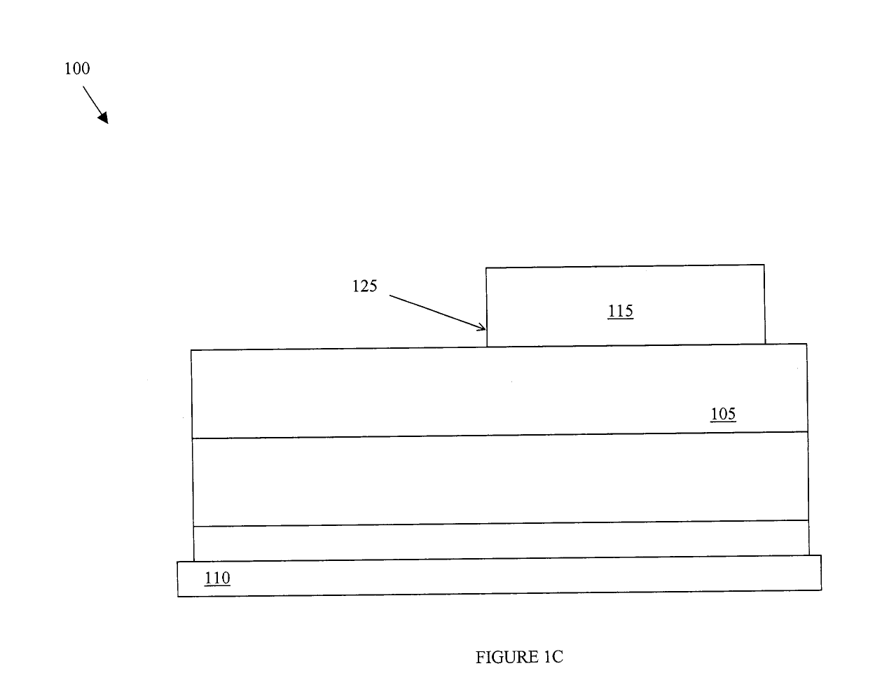

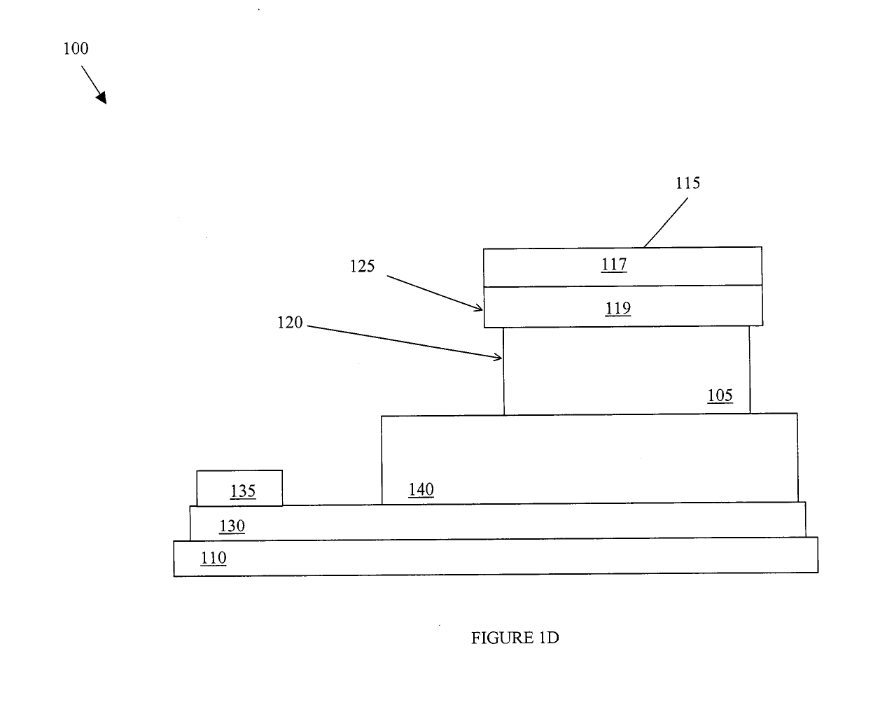

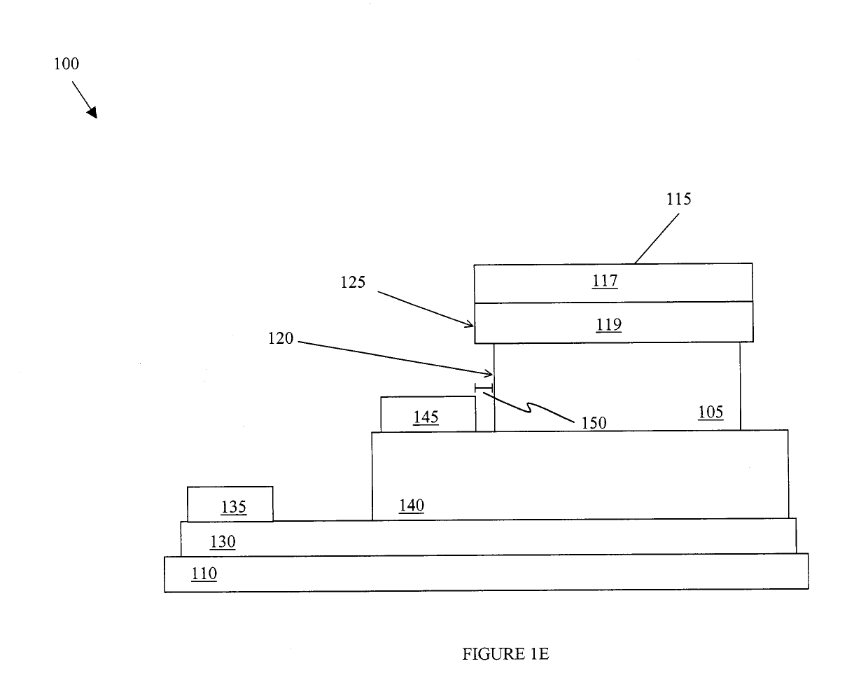

The present invention recognizes the advantageous use of a dry etch method to manufacture a bipolar transistor having reduced parasitic resistance and therefore increased performance compared to its predecessor bipolar transistors. FIGS. 1A-1E illustrate sectional views of one embodiment of a bipolar transistor 100 at various stages of manufacture.

As illustrated in FIG. 1A, a compound semiconductor 105 is deposited over or on a semiconductor substrate 110. The compound semiconductor 105 comprises Group IIA and IVA or Group IIIA and VA elements from the Periodic Table of the Elements (Groups 2 and 4 or Groups 3 and 5 of the IUPAC convention). As illustrated in FIG. 1B, a patterned metal layer 115 is formed on the compound semiconductor 105. Forming the metal layer 115 includes patterning the metal layer 115 so as to provide a layer with a desired perimeter 125 (FIG. 1C). Patterning the metal layer 115 is done using conventional techniques such as etching and liftoff. As shown in FIG. 1D, the compound semiconductor 105 is dry etched in a manner in which the metal layer 115 functions as an etch mask. Dry etching is carried out such that a perimeter of the compound semiconductor layer 120 is substantially coextensive with the perimeter of the metal layer 125.

The term substantially coextensive as used herein refers to a maximum uniform undercut on all sides of the compound semiconductor 105, and the respective sides of the patterned metal layer 115, following dry etching. It is desirable for the perimeter of the compound semiconductor 120 to be undercut with respect to the perimeter 125 of the patterned metal layer 115 by no more than 0.1 microns. As further discussed below, such small undercuts facilitate the subsequent deposition of metal in close proximity to, but not in physical contact with the compound semiconductor 105, so as to avoid electrical shorts.

In preferred embodiments, dry etching comprises exposing the compound semiconductor 105 and the patterned metal layer 115 to an etching plasma. In one embodiment, the conditions for dry etching via inductively coupled plasma reactive ion etch (ICP RIE) includes a bias power of between about 1 Watt and about 100 Watts and a source power of between about 20 Watts and about 2000 Watts and pressure of about 0.1 to about 20 mTorr. More preferably, the ICP RIE conditions include a power of between about 5 Watts and about 100 Watts and a source power of between about 100 Watts and about 1000 Watts. Preferably, dry etching is performed in a temperature range of between about 25° C. and about 300° C., and more preferably between about 150° C. and about 300° C. One skilled in the art would understand that the above-described conditions for dry etching are machine-dependent, and therefore vary such conditions according to the particular characteristics of the instrument used for dry etching.

Etchant gases provide both physical and chemical components to etching. For instance, during dry etching, the atoms of the physical component of the etchant gas are accelerated and bombard the compound semiconductor 105 to physically remove atoms from the semiconductor 105. A desirable feature of the physical component of the etchant gas is that the etch rate is substantially independent of the orientation of the crystal comprising the compound semiconductor 105. Suitable etchant gases include inert gases such as Argon, Hydrogen (H₂), Helium, Nitrogen (N₂) and Xenon. In certain embodiments it is advantageous to use etchant gases that comprise molecules of high mass, such as Argon. In other embodiment, however, the low cost and availability of gases such as Nitrogen (N₂) is preferred. The physical etch component obtained from gases comprise molecules of lower mass can be compensated by providing greater amounts of the gas. For instance, in certain embodiments, the etchant gas nitrogen is provided at between about 1.5 sccm and about 150 sccm.

It is also desirable for the etchant gas to include a chemical component. The chemical components are dissociated into free radicals that interact with and etch the compound semiconductor. Suitable chemical components include boron and chloride and more preferably boron trichloride. In certain preferred embodiments, for example, the etchant gas further includes boron trichloride gas provided at between about 0.1 sccm and about 50 sccm. Other suitable chemicals, such as chlorine (Cl₂) and fluorine (F₂) could be used.

The dry etching procedure of the present invention allows the production of a uniform undercut for the entire perimeter 125 of the compound semiconductor 105, irrespective of the orientation of the compound semiconductor crystal. For instance, in certain embodiments, a uniform undercut provides a ratio of etching rates along the [001] or [010] direction of the InP crystal versus the [011] or [011] direction ranges from about 0.8:1 to about 1.2:1 and more preferably about 1:1. The undercut is accordingly uniform, varying by less than +20 percent on all sides of the perimeter 125. Suitable dry etching conditions for achieving such uniform undercut ranges include exposing a compound semiconductor made of InP to BCl₃ and N₂ gases supplied at about 5 and 15 sccm, respectively. The gases are supplied at a pressure of about 2 mTorr and temperature of about 200° C., using bias and source powers of about 10 Watts and about 500 Watts, respectively.

In preferred embodiments the compound semiconductor 105 is an emitter 105 in the bipolar transistor 100, as shown in FIG. 1D. A compound semiconductor also can serve as a collector 130, as illustrated in FIG. 1D. Preferred compound semiconductor materials include indium gallium arsenide (InGaAs) indium phosphide (InP), indium aluminum phosphide (InAlP), indium gallium phosphide (InGaP) and combinations thereof. In certain embodiments, for example, it is advantageous for the emitter 105 to comprise a layer of InGaAs and a layer of InP (not individually shown). InGaAs, a narrow band gap material, is used to form the contact with the patterned metal layer 115, and InP, a wide band gap material, is below the InGaAs layer. The substrate 110 preferably is silicon, a second compound semiconductor or combinations of silicon and the second compound semiconductor. The compound semiconductor 105 is deposited over or on the substrate 110, using processes well known to those skilled in the art, such as molecular beam epitaxy or metal-organic chemical vapor deposition.

In preferred embodiments, the patterned metal layer 115 is an electrical contact for the emitter 105, as shown in FIG. 1D. A similarly formed metal layer 135 can also serve as a contact for the collector 130. The metal layers 115, 135 can comprise any metal commonly used in the semiconductor industry, such as gold, titanium, platinum, palladium or composite layers thereof. In certain preferred embodiments, the patterned metal layer 115 is a composite of two or more layers of such metals 117, 119, with the uppermost layer 117 being one of titanium, platinum or palladium. There can be similar configurations of the metal layer 135 serving as the contact for the collector 130.

It is desirable for the uppermost layer 117 of the patterned metal layer 115 to have a hardness and sufficient thickness to withstand the physical components of dry etching. In particular, it is desirable for the uppermost layer 117 to be a metal that is resistant to deterioration by sputtering that occurs during dry etching. In certain preferred embodiments, for example, the uppermost layer 117 of the patterned metal layer 115 is at least about 50 Angstroms thick, and more preferably between about 100 Angstroms and about 600 Angstroms thick.

In one preferred embodiment, for example, the patterned metal layer 115 is a composite of four layers, comprising, from bottom to top: palladium; platinum; gold; and palladium. The lowermost layer of palladium provides a good ohmic contact with the emitter 105, and preferably is between about 30 Angstroms and about 150 Angstroms thick, and more preferably about 50 Angstroms thick. The layer of platinum immediately above the lowermost layer of palladium provides a diffusion barrier for overlying gold layer. Preferably, the layer of platinum is between about 200 Angstroms and about 500 Angstroms thick and more preferably about 350 Angstroms thick. The gold layer comprises the bulk of the patterned metal layer 115, having a thickness between about 200 Angstroms and about 5000 Angstroms, and more preferably about 1000 Angstroms. The uppermost layer of palladium, is between about 100 Angstroms and about 600 Angstroms thick, and more preferably about 300 Angstroms thick.

Processes well known to those skilled in the arts, such as photoresist lithography, electron beam evaporation and chemical lift-off processes, are used to deposit and pattern the metal layers 115, 135. As illustrated in FIG. 1E, after the dry etching, a metal base electrode 145 is deposited on the base semiconductor 140. The metal base electrode 145 is a distance 150 near, but not in contact with the emitter 105. Preferably the distance is between about 0.01 microns and about 0.1 microns.

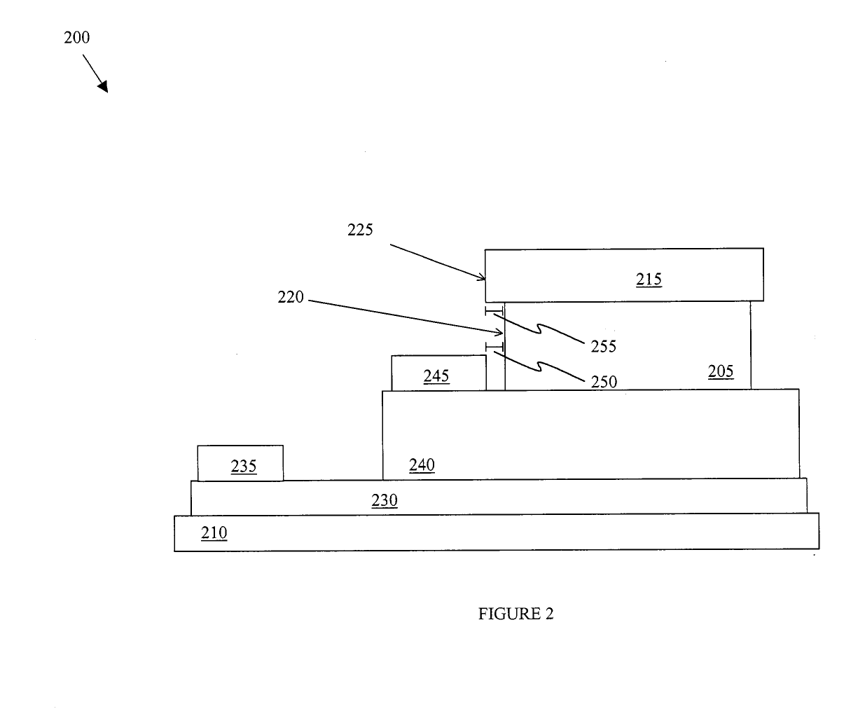

FIG. 2 illustrates a bipolar transistor 200, made by another embodiment of the manufacturing method illustrated by FIGS. 1A-1E. Like reference numbers are used in FIG. 2 for analogous structures in FIG. 1A-1E. Certain embodiments of the bipolar transistor 200 includes a semiconductor substrate 210, an emitter or collector 205 comprising a compound semiconductor and contacting a base 240 and a metal layer 215 over the emitter or collector 205. As discussed above, a perimeter 220 of the emitter or collector 205 is substantially coextensive with a perimeter 225 of the metal layer 215. Preferably, the undercut 255 between the perimeter 220 of the emitter or collector 205 and the perimeter 225 of the metal layer 215 is less than about 0.1 microns, and more preferably less than about 0.03 microns, but greater than about 0.01 microns.

In certain embodiments, where the metal layer 215 is over, and preferably contacting, the emitter 205, a metal base electrode 245 is located on the base 240. The metal base 245 has a gap 250 separating the perimeter 220 of the emitter 205 from the metal base electrode 245. It is desirable for the undercut 255 to prevent the metal base electrode 245 from contacting the perimeter of the emitter 220 when the metal 245 is deposited. Thus, in certain embodiments, the gap 250 between the perimeter 220 of the emitter 205 and the metal base electrode 245 is substantially equal to the undercut 255. In certain embodiments, for example, the gap 250 is less than about 0.1 microns, and more preferably, less than about 0.03 microns, but greater than 0.01 microns.

The small size of the gap 250 results in the bipolar transistor 200 having less parasitic resistance than conventionally made bipolar transistors where the gap 250 is larger. Consequently, the performance of the bipolar transistor 200 of the present invention is improved as compared to conventionally made bipolar transistors that have a larger gap 250 and corresponding larger parasitic resistance. For example, in preferred embodiments, the bipolar transistor 200 is configured to have a maximum oscillation frequency of greater than about 250, and more preferably greater than about 400 GHz. In contrast, a conventionally made bipolar transistor having a gap 250 of about 0.3 microns is expected to have a maximum oscillation frequency of less than 250 GHz.

One skilled in the art would understand that other embodiments of the bipolar transistor could be constructed with a different arrangement of collector, base, and emitter layers, than shown in FIG. 2. For instance, the bipolar transistor could comprise from bottom to top; an emitter layer; base layer; collector layer and overlying metal layer contacting the collector. In such embodiments, the metal layer overlying the collector functions as an etch mask, similar to that discussed above.

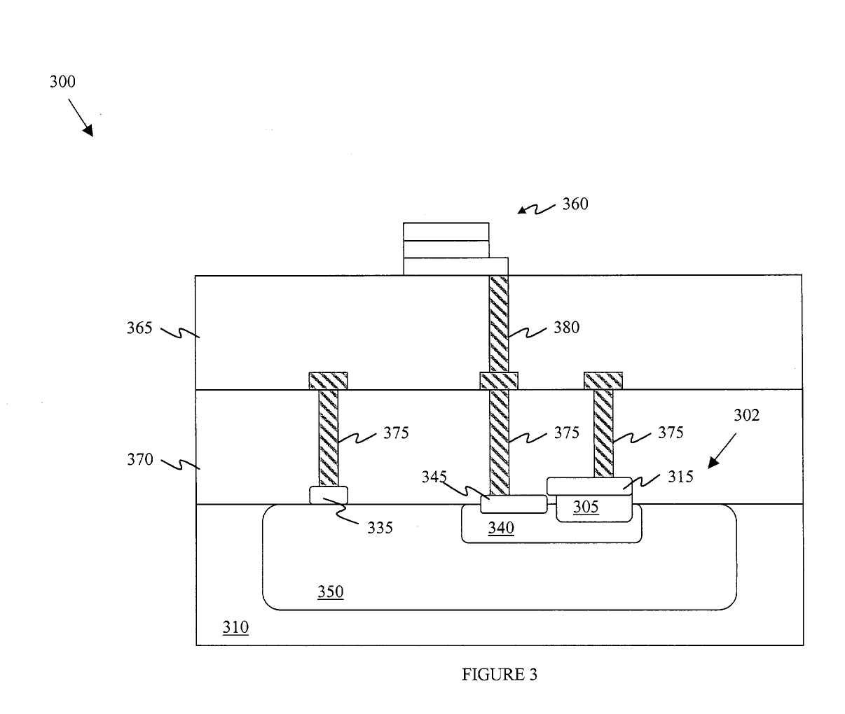

Yet another embodiment of the present invention, illustrated in FIG. 3, is an integrated circuit 300 that uses the methods and devices discussed above. Suitable uses for the integrated circuit 300 include broadband and high frequency amplifier applications. Any of the above-discussed embodiments of the bipolar transistor 302 may be used in the integrated circuit 300. Using like reference numbers to depict structures analogous to those of FIGS. 1 and 2, the bipolar transistor 302 comprises a collector 350, a semiconductor substrate 310, a base 340 on the collector 350, an emitter 305 on the base 340, a metal layer 315 over the emitter 305 and a metal base electrode 345 on the base 340. Examples of preferred bipolar transistors 302 include single and double heterojunction bipolar transistors.

The integrated circuit 300 also includes a conventional capacitor 360 located over the semiconductor substrate 305 and coupled to the bipolar transistor. In this particular embodiment, the capacitor 360 is located on a conventional dielectric layer 365. However, the capacitor 355 could be located at other levels within the integrated circuit 300, if so desired. The bipolar transistor 302 is insulated from upper metal levels by dielectric layers 365, 370. In addition, metal interconnections 375, contact the emitter metal layer 315, collector metal 335 and metal base 345. Interconnection 380 ultimately connects the capacitor 355 to the bipolar transistor 302. It should also be appreciated that other metal interconnections, which are not shown, interconnect the bipolar transistor 302 and other active or passive device structures that might exist within the integrated circuit 300 to form an operative integrated circuit 300.

Although the present invention has been described in detail, those of ordinary skill in the art should understand that they can make various changes, substitutions and alterations herein without departing from the scope of the invention.

1. A method of manufacturing a bipolar transistor, comprising:
depositing a compound semiconductor layer over a semiconductor substrate;
forming a patterned metal layer on said compound semiconductor layer; and
performing a dry etch of said compound semiconductor layer in a manner that uses said metal layer to align said dry etch.

2. The method as recited in claim 1, wherein performing said dry etch causes a perimeter of said compound semiconductor layer to be substantially coextensive with a perimeter of said metal layer.

3. The method as recited in claim 1, wherein said dry etching comprises exposing said compound semiconductor and said patterned metal layer to an inductively coupled plasma reactive ion etch.

4. The method as recited in claim 1, wherein performing said dry etch is conducted in a temperature range of between about 25° C. and about 300° C.

5. The method as recited in claim 1, wherein said dry etching includes an etchant gas comprising nitrogen.

6. The method as recited in claim 1, wherein said dry etching includes an etchant gas comprising chlorine and boron.

7. The method as recited in claim 6, wherein said etchant gas further includes boron trichloride gas provided at between about 0.1 sccm and about 50 sccm.

8. The method as recited in claim 1, wherein said metal layer is a contact for one of said emitter or collector.

9. The method as recited in claim 1, wherein said compound semiconductor is one of an emitter or a collector in said bipolar transistor.

10. The method as recited in claim 9, further includes depositing a base semiconductor over said collector depositing said emitter on said base semiconductor and depositing a metal base electrode on said base semiconductor a distance near but not contacting said emitter.

11. The method as recited in claim 10, wherein said distance is between about 0.01 and about 0.1 microns.

12-20 (Canceled)
